(19) United States
(12) Patent Application Publication
(10) Pub. No.: US 2024/0219502 A1
(43) Pub. Date: Jul. 4, 2024

(54) METHOD AND APPARATUS FOR MOTION-ROBUST RECONSTRUCTION IN MAGNETIC RESONANCE IMAGING SYSTEMS

(71) Applicant: CANON MEDICAL SYSTEMS CORPORATION, Otawara-shi (JP)

(72) Inventors: Hassan HAJI-VALIZADEH, Chagrin Falls, OH (US); Samir SHARMA, Solon, OH (US)

(73) Assignee: CANON MEDICAL SYSTEMS CORPORATION, Otawara-shi (JP)

(21) Appl. No.: 18/149,002

(22) Filed: Dec. 30, 2022

(51) Int. Cl. G01R 33/565; G01R 33/567

(52) U.S. Cl. CPC G01R 33/56509; G01R 33/5676; G01R 33/5608

(57) ABSTRACT

A method for motion correction in a magnetic resonance imaging system includes receiving data collected from imaging an object by the magnetic resonance imaging system, or image data reconstructed from the collected data. The method further includes generating motion-related information with respect to a motion of the object while the collected data is being collected. The motion-related information includes a certainty level of the collected data being corrupted by the motion of the object. The method also includes generating, based on the generated motion-related information and the received data or reconstructed image data, motion-corrected image data.

### FIELD

The present disclosure relates to image reconstruction in magnetic resonance imaging (MRI) systems. More especially, this disclosure relates to motion-robust MRI image reconstruction based on deep learning.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

As a non-invasive, non-ionizing imaging modality that provides high resolution and excellent contrast of soft tissues, MRI has been used as a powerful tool in early diagnosis of many diseases. Despite these advantages, the time-consuming k-space acquisition process often causes motion artifacts in clinical and research applications. Therefore, motion suppression or correction is considered as a crucial part of an MRI system.

Via single-shot echo-planar imaging, all the k-space data needed to reconstruct the final magnetic resonance (MR) image can be acquired in a single excitation pulse (“shot”). It significantly accelerates data acquisition and minimizes the possibility of motion artifacts, but suffers from low resolution and susceptibility artifacts. Multishot MRI is a promising data acquisition technique that can produce high-resolution images. However, in multi-shot MRI, the k-space data is acquired using a number of shots at different time points. Consequently, it is very sensitive to subject motion and even small levels of motion between consecutive shots can produce artifacts in the final MR image.

Therefore, it is desirable to address these and other deficiencies of current motion suppression/correction approaches.

### SUMMARY

The present disclosure relates to a method for motion correction in a magnetic resonance imaging system. The method includes receiving data collected from imaging an object by the magnetic resonance imaging system, or image data reconstructed from the collected data. The method further includes generating motion-related information with respect to a motion of the object while the collected data is being collected. The motion-related information includes a certainty level of the collected data being corrupted by the motion of the object. The method also includes generating, based on the generated motion-related information and the received data or reconstructed image data, motion-corrected image data.

The disclosure additionally relates to an apparatus for motion correction in a magnetic resonance imaging system. The apparatus includes processing circuitry. The processing circuitry is configured to receive data collected from imaging an object by the magnetic resonance imaging system, or image data reconstructed from the collected data. The processing circuitry is further configured to generate motion-related information with respect to a motion of the object while the collected data is being collected. The motion-related information includes a certainty level of the collected data being corrupted by the motion of the object. The processing circuitry is also configured to generate, based on the obtained motion-related information and the obtained data or reconstructed image data, motion-corrected image data.

Note that this summary section does not specify every embodiment and/or incrementally novel aspect of the present disclosure or claimed invention. Instead, the summary only provides a preliminary discussion of different embodiments and corresponding points of novelty. For additional details and/or possible perspectives of the disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows a non-limiting example of a block diagram of a motion-corrected reconstruction apparatus according to one embodiment of the present disclosure;

FIG. 2 shows a non-limiting example of a flow chart of a motion-corrected reconstruction process according to one embodiment of the present disclosure;

FIG. 3 shows a non-limiting example of a block diagram of motion-related information generation circuitry according to one embodiment of the present disclosure;

FIG. 4 shows a non-limiting example of a block diagram of motion-corrupted shot identification circuitry according to one embodiment of the present disclosure;

FIG. 5 shows a non-limiting example of a signal flow diagram in data-consistency weighting matrix generation according to one embodiment of the present disclosure;

FIG. 6 shows a non-limiting example of a flow chart of a training process for a neural network generating a data-consistency weighting matrix according to one embodiment of the present disclosure;

FIG. 7 shows a non-limiting example of a signal flow diagram in image data reconstruction according to one embodiment of the present disclosure;

FIG. 8 shows a non-limiting example of a deep-learning framework that reconstructs motion-corrected image data according to one embodiment of the present disclosure;

FIG. 9 shows a non-limiting example of a regularization unit according to one embodiment of the present disclosure;

FIG. 10 shows a non-limiting example of a flow chart of a training process for a deep-learning neural network according to one embodiment of the present disclosure;

FIG. 11 shows a non-limiting example of a deep-learning framework that reconstructs motion-corrected image data according to one embodiment of the present disclosure;

FIGS. 12A, 12B, and 12C show a correlation plot used to reject motion-corrupted shots, an MRI image reconstructed without motion-correction, and a motion-corrected reconstructed MRI image, according to one embodiment of the present disclosure;

FIG. 13 shows a scenario where a deep-learning framework is applied as post-reconstruction motion-correction, according to one embodiment of the present disclosure; and

FIG. 14 is a schematic block diagram of a magnetic resonance imaging system according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For example, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Furthermore, as used herein, the words “a,” “an,” and the like generally carry a meaning of “one or more,” unless stated otherwise.

MRI imaging process is inherently slow due to the need of accumulating sufficient data to fill the k-space. Subject motion during the prolonged k-space acquisition process can induce artifacts such as ghosting, blurring, geometric distortion, and decreased signal-to-noise ratio, and thus reduce MR image quality and diagnostic or scientific relevance.

For example, the imaging object might move during the acquisition of one shot out of a plurality of shots within scan, but which one of the plurality of shots the motion occurred in might be unknown. Thus, image reconstruction using all of the plurality of shots will include both the motion-corrupted shot (i.e., the shot during which the motion occurred) and other motion-free shots (i.e., the shots during which no motion occurred), and yield an image with motion artifacts. To improve the image quality, it is desirable to exclude the motion-corrupted data (i.e., respective k-space data points acquired by the motion-corrupted shot) in MR reconstruction.

Deep-learning-based algorithms that combine physics models with learned regularization priors can be used to reconstruct MR images. Typically, deep-learning reconstruction (DLR) is trained under ideal conditions (e.g., no motion). Consequently, a major limitation of such DLR is its sensitivity to motion. DLR is expected to perform optimally under ideal conditions where no motion exists, and the existence of motion can break the assumptions in the training and reduce the performance of DLR.

Therefore, it is desirable to incorporate motion information into DLR. Motion information can be isolated directly from imaging data, but this approach is limited by long processing times, and by a large number of confounding imaging factors, for example, trajectory errors, aliasing, and k-space trajectory. Since non-imaging data (e.g., navigator signals) is more robust to those confounding imaging factors, the present disclosure proposes to solve the challenges described above by using navigator signals in motion detection for DLR.

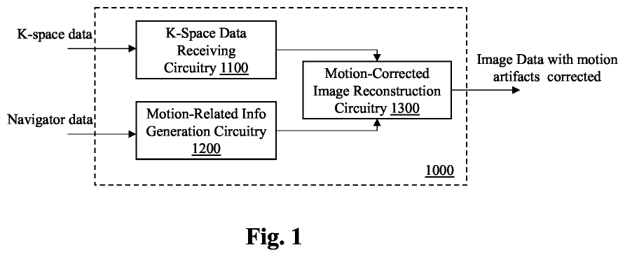

FIG. 1 shows a non-limiting example of a block diagram of a motion-correction reconstruction apparatus according to one embodiment of the present disclosure. The apparatus 1000 includes k-space data receiving circuitry 1100, motion-related information generation circuitry 1200, and motion-corrected image reconstruction circuitry 1300.

The k-space data receiving circuitry 1100 receives k-space data collected by the MRI scanner from an imaging object, and sends the k-space data to the motion-corrected image reconstruction circuitry 1300. Typically, the k-space data is acquired by a plurality of shots. Each shot acquires a number of k-space lines, and each k-space line includes a number of k-space points.

The motion-related information generation circuitry 1200 receives navigator data, generates motion-related information based on the navigator data, and sends the motion-related information to the motion-corrected image reconstruction circuitry 1300.

The motion-corrected image reconstruction circuitry 1300 can be a deep-learning framework that reconstructs motion-corrected image data based on the received k-space data and the motion-related information.

As will be described below, the navigator signals can be used not just to detect motion occurrence and estimate motion parameters for DLR, but also to account for the degree of certainty that imaging data is motion-free. Thus, the deep-learning framework can be trained to compensate for motion artifacts based on the degree of certainty that imaging data is motion-free. Such a strategy is beneficial because the deep learning framework can learn to be less aggressive when there is high certainty that data is motion-free, and to be more aggressive when there is low certainty that data is motion-free.

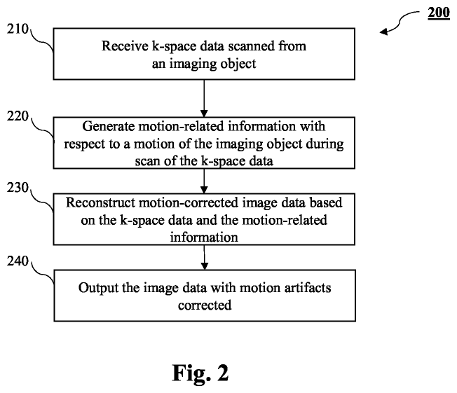

FIG. 2 shows a non-limiting example of a flow chart of a motion-correction reconstruction process 200 according to one embodiment of the present disclosure. In step 210, k-space data scanned by the MRI is received. In step 220, motion-related information is generated with respect a motion of the imaging object during scan of the k-space data. The motion-related information can include a motion parameter estimated and a certainty level that the k-space data is motion-free. In step 230, motion-corrected image data is reconstructed based on the k-space data and the motion-related information. In step 240, image data with motion artifacts corrected is outputted. This process will be described in more detail later in the description of the motion-related information generation circuitry 1200 and the motion-corrected image reconstruction circuitry 1300.

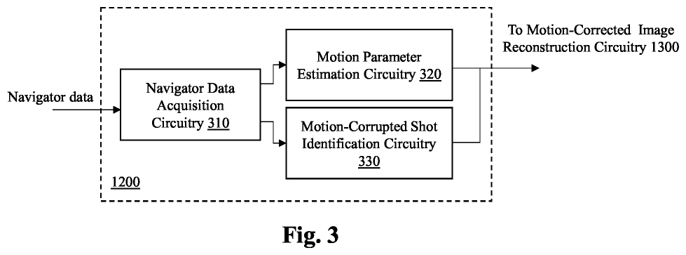

FIG. 3 shows a non-limiting example of a block diagram of motion-related information generation circuitry according to one embodiment of the present disclosure. The motion-related information generation circuitry 1200 includes navigator data acquisition circuitry 310, motion parameter estimation circuitry 320, and motion-corrupted shot identification circuitry 330.

The navigator data acquisition circuitry 310 acquires a navigator signal during every imaging shot. The navigator signals can be 3D volumes, 2D images, or 1D signals, and can be obtained from a variety of different sources, including but not limited to, non-imaging k-space echoes inserted into the MRI pulse sequence, respiratory bellows, ECG for cardiac motion detection, cameras with external markers, cameras without external markers, and pilot-tone-based motion detection, for example. The acquired navigator signals can be used to both detect motion existence and estimate motion values (e.g., parameters of a rigid-body motion).

From the acquired navigator data, the motion parameter estimation circuitry 320 estimates motion parameters (for example, a distance of a translation motion and/or an angle degree of a rotation motion). The motion parameter can be estimated from the navigator signals in any ways that one skilled in the art would recognize.

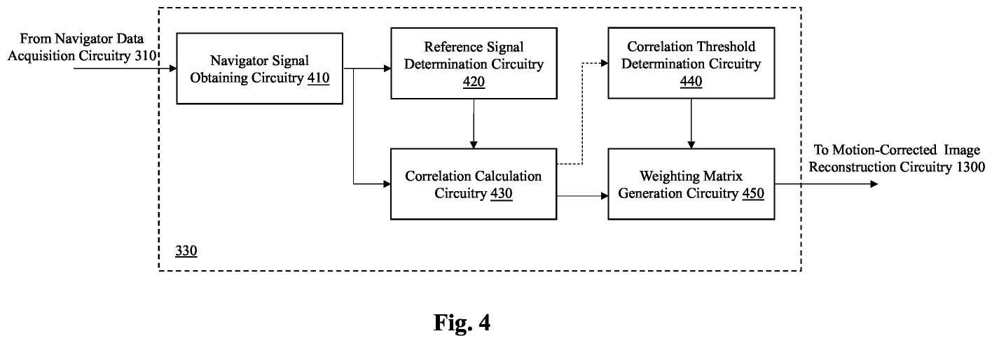

From the acquired navigator data, the motion-corrupted shot identification circuitry 330 performs motion shot detection and generates a data consistency weighting matrix. The identification of motion-corrupted shots will be described in details with reference to FIGS. 4-6.

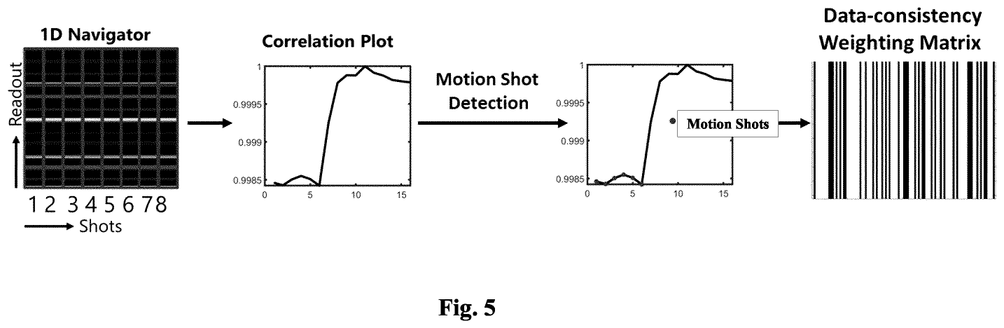

FIG. 4 shows a non-limiting example of a block diagram of motion-corrupted shot identification circuitry according to one embodiment of the present disclosure. The motion-corrupted shot identification circuitry 330 includes navigator signal obtaining circuitry 410, reference signal determination circuitry 420, correlation calculation circuitry 430, correlation threshold determination circuitry 440, and weighting matrix generation circuitry 450. The functions of the circuitry will be further described in the following in connection with the signal flow diagram illustrated in FIG. 5.

From the navigator data acquired by the navigator data acquisition circuitry 310, the navigator signal obtaining circuitry 410 obtains navigator signals that each corresponds to one of the plurality of shots for collecting the k-space data. In a non-limiting embodiment, the navigator signals can be derived from non-imaging k-space echoes by taking an inverse Fourier transform of the navigator k-space data, for example. Then, the navigator signal obtaining circuitry 410 sends the obtained navigator signals to the reference signal determination circuitry 420 and the correlation calculation circuitry 430.

Based on the received navigator signals, the reference signal determination circuitry 420 determines and sends a reference navigator signal to the correlation calculation circuitry 430. In an exemplary example, a navigator signal that has the highest correlation to all other navigator signals can be selected as the reference navigator signal. In an alternative example, an average of all navigator signals can be determined as the reference navigator signal. One skilled in the art can appreciate that other approaches are possible; for example, a navigator signal acquired during a known rest state (i.e., when the imaging object is still) can be used as the reference navigator signal.

The correlation calculation circuitry 430 calculates the correlation between each navigator signal to the reference navigator signal. A correlation plot can be generated based on the calculated correlations. For example, FIG. 5 shows a correlation plot generated from 1D navigator signals acquired along the readout direction. In the correlation plot, the horizontal axis represents an index of the shots, and the vertical axis the correlation between the corresponding navigator signal and the reference navigator signal.

The correlation threshold determination circuitry 440 determines and sends one or more correlation thresholds to the weighting matrix generation circuitry 450. The thresholds can be empirically derived in any possible ways to enable motion detection based on the navigator data.

Based on the correlations received from the correlation calculation circuitry 430 and further based on the one or more correlation thresholds received from the correlation threshold determination circuitry 440, the weighting matrix generation circuitry 450 differentiates motion-corrupted shots (represented by the points on the correlation plot in FIG. 5) from motion-free shots and generates the data-consistency weighting matrix exemplarily shown in FIG. 5.

In a non-limiting embodiment, an absolute correlation threshold can be used. For example, if the correlation between a navigator signal and the reference navigator signal is less than a threshold a, the corresponding shot is determined as motion corrupted.

In another embodiment, a standard-deviation-type threshold can be used. For example, if the correlation between a navigator signal and the reference navigator signal is less than μ−α×σ, the corresponding shot is determined as motion corrupted. Here, the mean μ and the standard deviation σ can be derived using correlations calculated for all shots (or a subset of those shots).

Alternatively, a maximum number of shots, among all the shots, can be determined as motion corrupted. In this scheme, the number of motion-corrupted shots will not be more than σ multiple of a ratio threshold a and the total number of the shots, for example. Without departing from the scope of the present disclosure, any combination of the above thresholds and/or other thresholds can be used so as to improve motion detection performance.

In the embodiments above, as the shots are classified as motion-free and motion-corrupted, the weighting matrix generation circuitry 450 can generate a binary weighting matrix. Each element of the matrix can have either a value indicating a high certainty level of the corresponding k-space points being motion-free, or another value indicating a high certainty level of the corresponding k-space points being corrupted by the motion of the imaging object. The weighting matrix will be incorporated by the image reconstruction circuitry 1300 in image data reconstruction.

In a further alternative embodiment, a set of thresholds can be adopted to achieve a finer classification. The weighting elements each can have a value from a predefined range, leading to a non-binary weighting matrix. When the comparison of the correlation and the set of thresholds indicates a stronger correlation, a value approaching a first end of the predefined range can be assigned to represent a higher certainty level of the corresponding k-space points not being corrupted by the motion. In response to the comparison indicating a weaker correlation, a value approaching a second end of the predefined range to represent a higher certainty level of the k-space points being corrupted by the motion.

In an exemplary scenario where two empirical absolute thresholds α1 and α2 are used, when the correlation is less than α1, the value of corresponding matrix elements can be set at 0; when the correlation is between α1 and α2, the value of corresponding matrix elements can be set at 0.5; and when correlation is greater than α2, the value of corresponding matrix elements can be set at 1.

Alternatively, instead of using one or more empirically derived thresholds, a neural network can be trained to infer the certainty from the generated correlation plot, or directly from raw navigator signals.

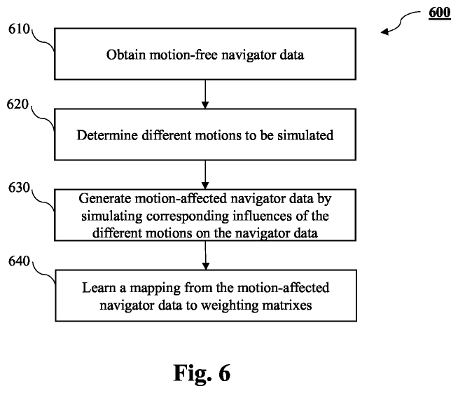

FIG. 6 shows a non-limiting example of a flow chart of a training process for a neural network generating a data-consistency weighting matrix according to one embodiment of the present disclosure. The training process 600 begins in step 610 by obtaining motion-free navigator data.

In step 620, different motions to be simulated are determined, including but not limited to, rigid-body motions such as translations and rotations, through-plane motions, general motion-related signal degradation, etc.

In step 630, motion-affected navigator data is generated by simulating corresponding influences of different motions on the navigator data. For 3D and 2D navigator signals, translation and rotation can be simulated. For 1D navigator signals, only translation along the readout direction can be simulated. Through-plane motion can be simulated as an intensity change in navigator signals for selected shots. General motion-related signal degradation also can be simulated (i.e., transient unsteady-state magnetization).

In step 640, using the generated navigator data, the neural network is trained to learn a mapping from the motion-affected navigator data to the weighting matrixes.

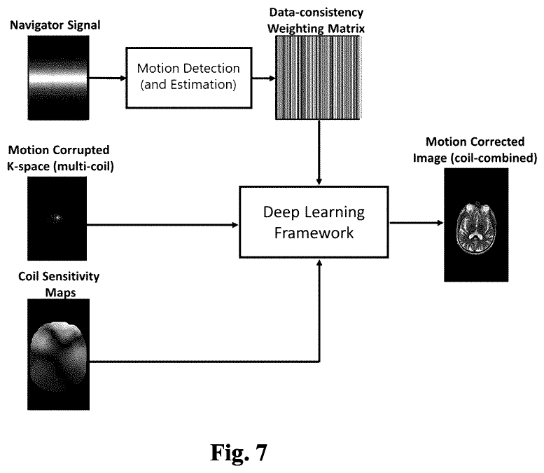

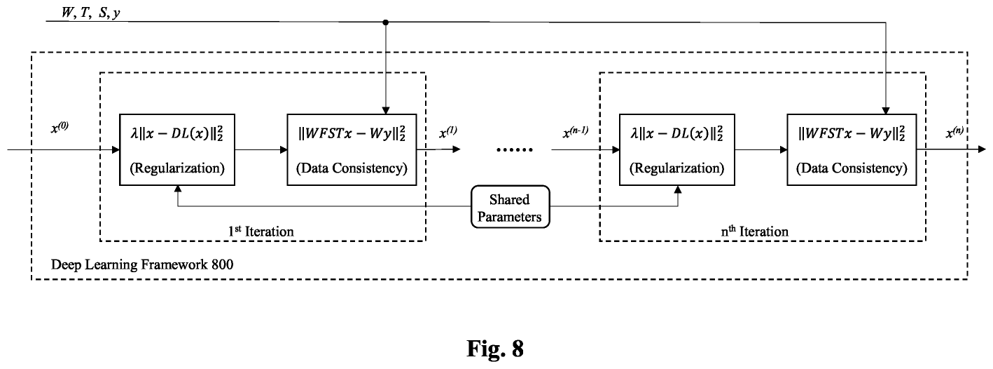

FIG. 7 shows a non-limiting example of a signal flow diagram in image data reconstruction according to one embodiment of the present disclosure. The received navigator data first goes through the motion detection (and motion parameter estimation) process, resulting in motion-related information, i.e., the data-consistency weighting matrix and the motion parameters (not shown in the FIG. 7). Motion corrupted k-space data and coil sensitivity maps are inputted into the motion-corrected imaging reconstruction circuitry (i.e., the deep learning framework). At the output of the deep learning framework, coil-combined motion-corrected image data is produced. Although FIG. 8 shows an embodiment in the multicoil parallel imaging scheme, the present disclosure can also be applied to regular non-parallel imaging.

FIG. 8 shows a non-limiting example of a deep-learning framework that reconstructs motion-corrected image data according to one embodiment of the present disclosure. To reconstruct MR image, the deep-learning framework in FIG. 8 minimizes the following cost function:

$${x}_{reconstructed} = {min}_{x} {‖ WFSTx - Wy ‖}_{2}^{2} + λ {‖ x - D L ( x ) ‖}_{2}^{2}$$

where x_{reconstructed} denotes a motion-free and aliasing free image to be reconstructed, W denotes the data consistency weighting matrix generated from the navigator signals, F denotes the Fourier transform operator, S denotes the receiver coil sensitivity matrix, T denotes the motion parameter matrix estimated from the navigator signals, x denotes the image that is being optimized, y denotes the motion corrupted k-space data acquired from the imaging object by the MRI scanner, λ denotes the regularization weight, and DL(x) is the output of regularization unit.

As shown in FIG. 8, the framework alternates between the regularization term, which is based on a trained neural network, and the data consistency enforcement term, which encourages data fidelity. This unrolled iterative structure allows end-to-end optimization of the MR reconstruction algorithm.

By incorporating the weighting matrix into the training stage, the framework of FIG. 8 is able to achieve better reconstruction. That is, the neural-network-based regularization unit can be trained to be more or less aggressive in accordance with a degree of certainty of the k-space data is motion-corrupted or motion-free. More specifically, the neural network learns to have a greater influence on the final image when an information derived from the navigator signals indicates high certainty that the corresponding k-space points are motion-corrupted, and to have less impact on the final image when the information indicates high certainty that the corresponding k-space points are motion free.

In an embodiment of the present disclosure, the data consistency term of FIG. 8 can be implemented by a conjugate gradient iteration algorithm. Other approaches are possible, including but not limited to, a proximal gradient algorithm, an orthogonal matching pursuit algorithm, an iterative hard thresholding algorithm, a split Bregman-based algorithm, and a gradient descent algorithm, for example.

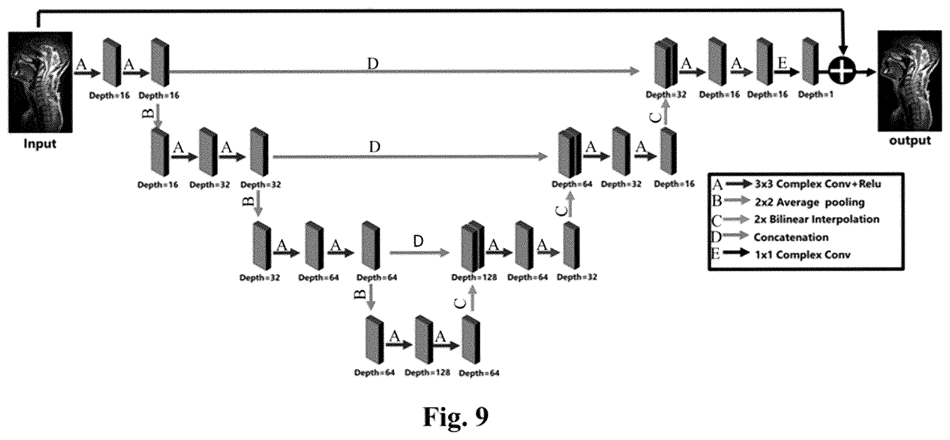

FIG. 9 shows a non-limiting example of a regularization unit according to one embodiment of the present disclosure. The neural-network-based regularization unit shown in FIG. 9 is a U-net convolutional neural network (CNN) combined with complex-valued operations, which has improved performance in DLR. Other CNN architectures can be used, including but not limited to, a residual U-net, a residual network, an inception-residual network, and a linear convolutional network, for example.

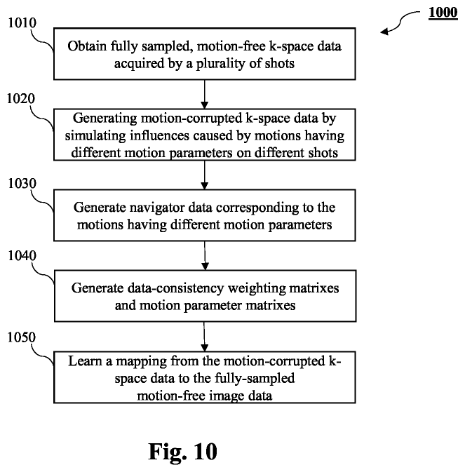

FIG. 10 shows a non-limiting example of a flow chart of a training process for a deep learning neural network according to one embodiment of the present disclosure. In step 1010, fully-sampled and motion-free k-space data is collected by a plurality of shots. In step 1020, using an MRI forward model, motion-corrupted k-space data is generated by simulating influences of motions having different motion parameters on different shots. The simulated motions include, but are not limited to, rigid-body motions, for example, translation within a range of ±5 mm and rotations within a range of ±5 degrees. The shots to be corrupted can be selected randomly or based on previously specified motion trajectory.

In step 1030, navigator data is generated based on the different motion parameters. In step 1040, the motion parameter matrixes Ts can be generated by adding noise to the different motion parameters, and the data-consistency weighting matrixes Ws can be generated by applying empirically derived thresholds to correlation plots derived from the navigator data. The noise is added to simulate the errors potentially produced in estimating motion parameters from navigator data.

In step 1050, with fully-sampled motion-free coil-combined images as a target, the motion-robust DLR is trained using the simulated motion-corrupted k-space data, motion parameter matrixes Ts, and the data-consistency weighting matrixes Ws, so as to learn a mapping from motion-corrupted k-space data to motion-free reconstructed image data.

In an alternative embodiment, undersampled k-space data can be simulated and used as training data as well. In this way, the DLR can learn to reconstruct motion robust images in a undersampling scheme, including but not limited to, parallel imaging sampling, partial FOV sampling, compressed sensing sampling, and partial Fourier sampling, etc.

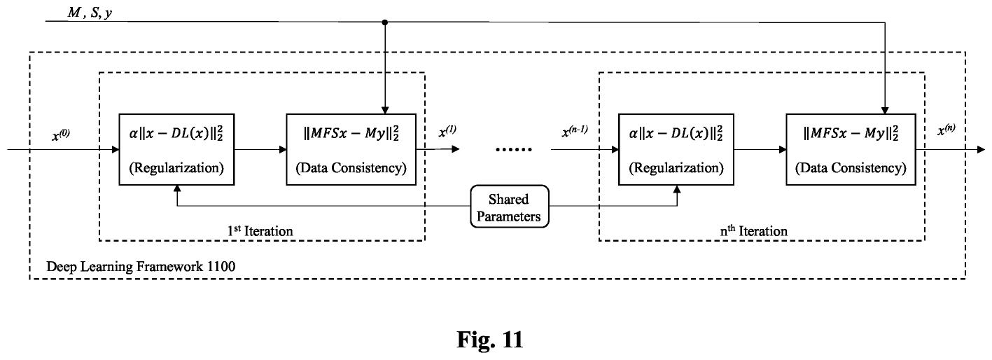

FIG. 11 shows a non-limiting example of a deep learning framework that reconstructs motion-corrected image data according to one embodiment of the present disclosure. In this embodiment, a binary weighting matrix (or binary masks) M is used. For k-space points that have high certainty of being motion-free, the corresponding weighting elements are set at “1.” For k-space points that have high certainty of being motion-corrupted (and optionally, for those unacquired data points in a undersampling scheme), the corresponding weighting elements are set at “0,” which means these k-space points are to be rejected in image reconstruction. Therefore, this embodiment can omit the operation of estimating a motion parameter matrix T from the navigator signals.

The motion-robust DLR shown in FIG. 11 minimizes the following cost function:

$${x}_{reconstructed} = {min}_{x} {‖ MFSx - My ‖}_{2}^{2} + α {‖ x - D L ( x ) ‖}_{2}^{2}$$

where x_{reconstructed} denotes the motion-free and aliasing-free image to be reconstructed, M denotes the binary data consistency weighting matrix representing data rejection/acceptance, F denotes the Fourier transform operator, S denotes the receiver coil sensitivity matrix, DL(x) is the output of the regularization unit, λ denotes the regularization weight, x denotes the image that is being optimized, and y denotes the motion-corrupted k-space acquired from the imaging object by the MRI scanner.

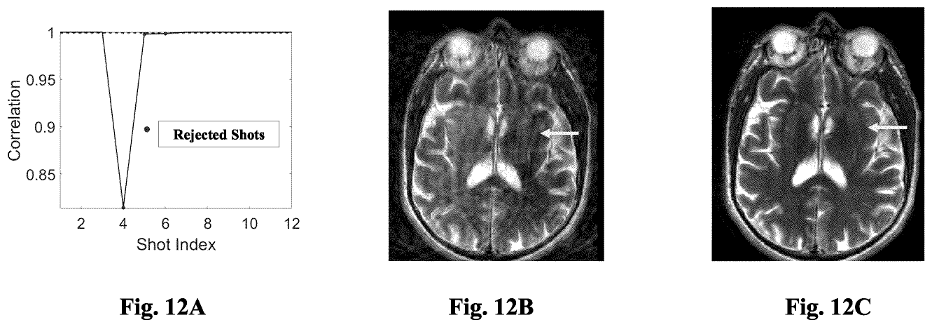

FIGS. 12A, 12B, and 12C show a correlation plot used to reject motion-corrupted shots, an MRI image reconstructed without motion-correction, and a motion-corrected reconstructed MRI image, according to the embodiment shown in FIG. 11. As shown in FIG. 12A, an exemplary absolute threshold of 0.999 is used to generate the binary data-consistency weighting matrix M. As a result, the k-space points acquired by the shots 4, 5, and 6 are rejected and thus not used in image reconstruction, because their corresponding correlations are less than 0.999. Compared with the T2w FSE brain image reconstructed without shot rejection, DLR demonstrates satisfactory improvement in image quality, for example, with respect to the part indicated by the arrows in FIGS. 12B and 12C.

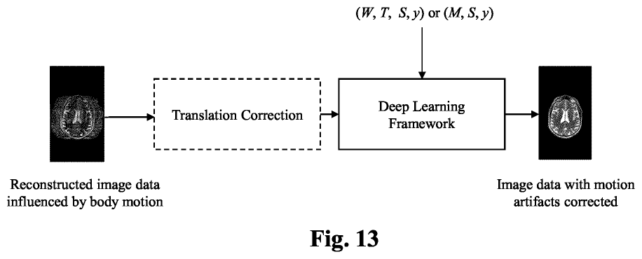

In the embodiments of FIGS. 8 and 11, motion correction is performed as part of the deep-learning reconstruction stage. The combination of DLR with motion correction enables direct targeting of motion corrupted k-space data rather than all k-space data. In an alternative approach, the DLR and motion correction can be applied sequentially. FIG. 13 shows an exemplary scenario where a deep learning framework is applied as post-reconstruction motion-correction, according to one embodiment of the present disclosure. The image data is reconstructed from motion-corrupted k-space data, and then inputted to a deep learning framework according to the present disclosure. Optionally, additional translation correction can be performed before the deep learning framework.

Moreover, the motion-robust DLR of this disclosure can be combined with real-time feedback (i.e., prospective motion correction) to improve image quality. Typically, the real-time feedback will provide instructions to the MR scanner to re-acquire the motion-corrupted data, at which point, the motion-corrupted data is rejected or thrown out. In an embodiment of the disclosure, when motion is detected during a scan, real-time feedback can be provided to instruct the MRI scanner to re-acquire the motion-corrupted data points. Then, the acquired data points and their respective degree of certainty of being motion-free are used to generate the data consistency weighting matrix. Based on the data consistency weighting matrix generated, the data points that are originally determined as motion-free, the data points that are originally determined as motion-corrupted, and the re-acquired data are all be incorporated into the DLR-based MRI reconstruction. In this way, the MR image produced can have higher SNR and better image quality.

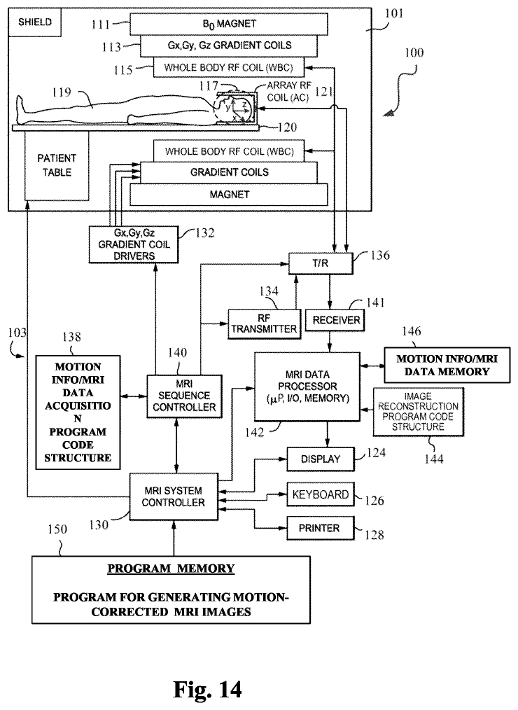

Referring now to FIG. 14, a non-limiting example of a magnetic resonance imaging (MRI) system 100 is shown. The MRI system 100 depicted in FIG. 14 includes a gantry 101 (shown in a schematic cross-section) and various related system components 103 interfaced therewith. At least the gantry 101 is typically located in a shielded room. The MRI system geometry depicted in FIG. 14 includes a substantially coaxial cylindrical arrangement of the static field B0 magnet 111, a Gx, Gy, and Gz gradient coil set 113, and a large whole-body RF coil (WBC) assembly 115. Along a horizontal axis of this cylindrical array of elements is an imaging volume 117 shown as substantially encompassing the head of a patient 119 supported by a patient table 120.

One or more smaller array RF coils 121 can be more closely coupled to the patient's head (referred to herein, for example, as “imaging object” or “object”) in imaging volume 117. As those in the art will appreciate, compared to the WBC (whole-body coil), relatively small coils and/or arrays, such as surface coils or the like, are often customized for particular body parts (e.g., arms, shoulders, elbows, wrists, knees, legs, chest, spine, etc.). Such smaller RF coils are referred to herein as array coils (AC) or phased-array coils (PAC). These can include at least one coil configured to transmit RF signals into the imaging volume, and a plurality of receiver coils configured to receive RF signals from an object, such as the patient's head, in the imaging volume.

The MRI system 100 includes an MRI system controller 130 that has input/output ports connected to a display 124, a keyboard 126, and a printer 128. As will be appreciated, the display 124 can be of the touch-screen variety so that it provides control inputs as well. A mouse or other I/O device(s) can also be provided.

The MRI system controller 130 interfaces with an MRI sequence controller 140, which, in turn, controls the Gx, Gy, and Gz gradient coil drivers 132, as well as the RF transmitter 134, and the transmit/receive switch 136 (if the same RF coil is used for both transmission and reception). The RF transmitter 134 may be composed of two or more transmitter channels for driving two or more RF transmit coils or ports on coils, as is used for RF shimming. The MRI sequence controller 140 includes suitable program code structure 138 for implementing MRI imaging (also known as nuclear magnetic resonance, or NMR, imaging) techniques including B1 field shimming. MRI sequence controller 140 can be configured for MR imaging with or without parallel imaging. Moreover, the MRI sequence controller 140 can facilitate one or more preparation scan (pre-scan) sequences, and a scan sequence to obtain a main scan magnetic resonance (MR) image (referred to as a diagnostic image). MR data from pre-scans can be used, for example, to determine shimming parameters for RF coils 115 and/or 121.

The MRI system components 103 include an RF receiver 141 providing input to data processor 142 so as to create processed image data, which is sent to display 124. The MRI data processor 142 is also configured to access previously generated MR data, images, navigator data, system configuration parameters 146, and/or program code structures 144 and 150.

In one embodiment, the MRI data processor 142 includes processing circuitry. The processing circuitry can include devices such as an application-specific integrated circuit (ASIC), configurable logic devices (e.g., simple programmable logic devices (SPLDs), complex programmable logic devices (CPLDs), and field programmable gate arrays (FPGAs), and other circuit components that are arranged to perform the functions recited in the present disclosure, such as described with respect to FIGS. 1-4, 8, and 11.

The processor 142 executes one or more sequences of one or more instructions contained in the program code structures 144 and 150. Alternatively, the instructions can be read from another computer-readable medium, such as a hard disk or a removable media drive. One or more processors in a multi-processing arrangement can also be employed to execute the sequences of instructions contained in the program code structures 144 and 150. In alternative embodiments, hard-wired circuitry can be used in place of or in combination with software instructions. Thus, the disclosed embodiments are not limited to any specific combination of hardware circuitry and software. For example, the program code structure 150 can store instructions that when executed perform the method 200.

Additionally, the term “computer-readable medium” as used herein refers to any non-transitory medium that participates in providing instructions to the processor 142 for execution. A computer readable medium can take many forms, including but not limited to, non-volatile media or volatile media. Non-volatile media includes, for example, optical, magnetic disks, and magneto-optical disks, or a removable media drive. Volatile media includes dynamic memory.

Also illustrated in FIG. 14 is a generalized depiction of an MRI system program storage (memory) 150, where stored program code structures such as instructions to perform the method 200 are stored in non-transitory computer-readable storage media accessible to the various data processing components of the MRI system 100. As those in the art will appreciate, the program store 150 can be segmented and directly connected, at least in part, to different ones of the system 103 processing computers having most immediate need for such stored program code structures in their normal operation (i.e., rather than being commonly stored and connected directly to the MRI system controller 130).

Additionally, the MRI system 100 as depicted in FIG. 14 can be utilized to practice exemplary embodiments described herein. The system components can be divided into different logical collections of “boxes” and typically comprise numerous digital signal processors (DSP), microprocessors and special purpose processing circuits (e.g., for fast A/D conversions, fast Fourier transforming, array processing, etc.). Each of those processors is typically a clocked “state machine” wherein the physical data processing circuits progress from one physical state to another upon the occurrence of each clock cycle (or predetermined number of clock cycles).

Furthermore, not only does the physical state of the processing circuits (e.g., CPUs, registers, buffers, arithmetic units, etc.) progressively change from one clock cycle to another during the course of operation, the physical state of associated data storage media (e.g., bit storage sites in magnetic storage media) is transformed from one state to another during operation of such a system. For example, at the conclusion of an image reconstruction process and/or sometimes an image reconstruction map (e.g., coil sensitivity map, unfolding map, ghosting map, a distortion map etc.) generation process, an array of computer-readable accessible data value storage sites in physical storage media will be transformed from some prior state to a new state wherein the physical states at the physical sites of such an array vary between minimum and maximum values to represent real world physical events and conditions. As those in the art will appreciate, such arrays of stored data values represent and also constitute a physical structure, as does a particular structure of computer control program codes that, when sequentially loaded into instruction registers and executed by one or more CPUs of the MRI system 100, causes a particular sequence of operational states to occur and be transitioned through within the MRI system 100.

Numerous modifications and variations are possible in light of the above teachings. It is therefore to be understood that within the scope of the appended claims, the disclosure can be practiced otherwise than as specifically described herein.

Embodiments of the present disclosure may also be as set forth in the following parentheticals.

(1) A method for motion correction in a magnetic resonance imaging system, comprising: receiving data collected from imaging an object by the magnetic resonance imaging system, or image data reconstructed from the collected data; generating motion-related information with respect to a motion of the object while the collected data is being collected, the motion-related information including a certainty level of the collected data being corrupted by the motion of the object; and generating, based on the generated motion-related information and the received data or reconstructed image data, motion-corrected image data.

(2) The method of (1), wherein the collected data is k-space data acquired by a plurality of shots, each shot acquiring a plurality of k-space lines, each k-space line comprising a plurality of k-space points, and the step of generating the motion-related information further comprises: receiving a plurality of navigator signals, each navigator signal being acquired during one of the plurality of shots, estimating, based on the plurality of navigator signals, a motion parameter of the motion of the object, the motion parameter being included in the motion-related information, and generating, based on the plurality of navigator signals, a data-consistency weighting matrix, the data-consistency weighting matrix comprising a plurality of weighting elements, each weighting element corresponding to a k-space point and representing a certainty level of the corresponding k-space point being corrupted by the motion of the object.

(3) The method of (2), wherein the step of generating the data-consistency weighting matrix further comprises: deriving, based on the received plurality of navigator signals, a reference navigator signal; calculating a corresponding correlation between each navigator signal of the plurality of navigator signals and the reference navigator signal; assigning, based on a comparison of the correlation calculated for each navigator signal, of the plurality of navigator signals, with an empirical correlation threshold, a particular value to a number of weighting elements of the weighting matrix, the number of weighting elements corresponding to a number of k-space points acquired by one of the plurality of shots that corresponds to the navigator signal.

(4) The method of (3), wherein the assigned particular value is a value within a predefined range, and the assigning step further comprises: assigning, in response to the comparison indicating a stronger correlation, the particular value, which approaches a first end of the predefined range to represent a higher certainty level of the number of k-space points not being corrupted by the motion, and assigning, in response to the comparison indicating a weaker correlation, the particular value, which approaches a second end of the predefined range to represent a higher certainty level of the number of k-space points being corrupted by the motion.

(5) The method of (3), wherein the assigned particular value is either a first predefined value or a second predefined value, and the assigning step further comprises: assigning, in response to the comparison indicating the correlation beyond the empirical correlation threshold, the first predefined value to represent a high certainty level of the number of k-space points not being corrupted by the motion, and assigning, in response to the comparison indicating the correlation short of the empirical correlation threshold, the second predefined value to represent a high certainty level of the number of k-space points being corrupted by the motion.

(6) The method of (5), wherein the second predefined value is set at 0 to reject the number of k-space points because of the motion, such that the number of k-space points are not to be used in reconstruction of the image data, and the estimating step is omitted.

(7) The method of (2), wherein the step of generating the data consistency weighting matrix further comprises: inputting the plurality of navigator signals to a neural network; and obtaining, as the data consistency weighting matrix, an output of the neural network.

(8) The method of (7), further comprising: obtaining motion-free navigator data; determining different motions to be simulated; generating motion-affected navigator data by simulating a corresponding influence of each motion on the motion-free navigator data; using the motion-free navigator data and the motion-affected navigator data to train the neural network, so as to learn a mapping from the motion-affected navigator data to a corresponding data consistency weighting matrix.

(9) The method of (2), wherein the step of generating the data consistency weighting matrix further comprises: determining, based on the plurality of navigator signals, a reference navigator signal; calculating a corresponding correlation between each navigator signal of the plurality of navigator signals and the reference navigator signal; inputting the calculated correlations to a neural network; and obtaining, as the data consistency weighting matrix, an output of the neural network.

(10) The method of (2), wherein the step of generating the motion-corrected image data further comprising: applying the received data or the reconstructed image data, the weighting matrix, and the motion parameter to a neural network; and obtaining, as the motion-corrected image data, an output of the neural network.

(11) The method of (10), wherein the applying step further comprises applying the obtained data or the reconstructed image data, the generated weighting matrix, and the estimated motion parameter to a model-driven deep learning framework having a pre-determined number of iterations, where each iteration comprises a regularization unit and a data consistency unit.

(12) The method of (11), wherein the regularization unit is a U-net, a residual U-net, a residual network, an inception-residual network, or a linear convolutional network.

(13) The method of (12), wherein the regularization unit is a complex U-net, and a plurality of parameters of the complex U-net are shared across the pre-determined number of iterations.

(14) The method of (11), wherein the data consistency unit uses a conjugate gradient iteration algorithm, a proximal gradient algorithm, an orthogonal matching pursuit algorithm, an iterative hard thresholding algorithm, a split Bregman-based algorithm, or a gradient descent algorithm.

(15) The method of (10), further comprising: obtaining fully-sampled motion-free k-space data acquired by a plurality of shots; generating motion-corrupted k-space data by simulating corresponding influences caused by motions having different motion parameters on different shots; generating navigator data corresponding to the motions having different motion parameters; generating data-consistency weighting matrixes based on the navigator data; using the fully-sampled motion-free k-space data, the motion-corrupted k-space data, the data-consistency weighting matrixes, and the motion parameters to train the deep learning framework, so as to learn a mapping from the motion-corrupted k-space data to the fully-sampled motion-free image data.

(16) The method of (2), wherein the step of receiving the plurality of navigator signals further comprises acquiring the plurality of navigator signals from a non-imaging k-space echo inserted into a pulse sequence of the magnetic resonance imaging system, a respiratory bellow, an electrocardiogram signal, a camera with an external marker, a camera without an external marker, or a pilot-tone-based motion detection signal.

(17) The method of (2), wherein the step of receiving the plurality of navigator signals further comprises acquiring the plurality of navigator signals in a form of a 3D volume, a 2D image, or a 1D signal.

(18) The method of (2), wherein the estimating step further comprises estimating, as the motion parameter, a distance of a translation and/or an angle degree of a rotation.

(19) A method for motion correction in a magnetic resonance imaging system, comprising: acquiring k-space data from imaging an object by the magnetic resonance imaging system; determining, based on a plurality of navigator signals acquired while the k-space data is being acquired, a certainty level of each k-space point of the acquired k-space data being corrupted by a motion of the object; identifying, based on the determined certainty levels, a number of k-space points corrupted by the motion of the imaging object; re-acquiring, with respect to the identified motion-corrupted k-space points, a number of k-space points; determining, based on a plurality of navigator signals acquired while the re-acquired k-space points are being re-acquired, a certainty level of each k-space point of the re-acquired k-space data being corrupted by a motion of the object; and using the acquired k-space data, the re-acquired k-space points, and corresponding certainty levels to reconstruct a magnetic resonance image.

(20) A apparatus for motion correction in a magnetic resonance imaging system, comprising processing circuitry configured to: receive data collected from imaging an object by the magnetic resonance imaging system, or image data reconstructed from the collected data; generate motion-related information with respect to a motion of the object while the collected data is being collected, the motion-related information including a certainty level of the collected data being corrupted by the motion of the object; and generate, based on the obtained motion-related information and the obtained data or reconstructed image data, motion-corrected image data.

Those skilled in the art will also understand that there can be many variations made to the operations of the techniques explained above while still achieving the same objectives of the disclosure. Such variations are intended to be covered by the scope of this disclosure. As such, the foregoing descriptions of embodiments of the disclosure are not intended to be limiting. Rather, any limitations to embodiments of the disclosure are presented in the following claims.

What is claimed is:

1. A method for motion correction in a magnetic resonance imaging system, comprising:
receiving data collected from imaging an object by the magnetic resonance imaging system, or image data reconstructed from the collected data;
generating motion-related information with respect to a motion of the object while the collected data is being collected, the motion-related information including a certainty level of the collected data being corrupted by the motion of the object; and
generating, based on the generated motion-related information and the received data or reconstructed image data, motion-corrected image data.

2. The method of claim 1, wherein the collected data is k-space data acquired by a plurality of shots, each shot acquiring a plurality of k-space lines, each k-space line comprising a plurality of k-space points, and
the step of generating the motion-related information further comprises:
receiving a plurality of navigator signals, each navigator signal being acquired during one of the plurality of shots,
estimating, based on the plurality of navigator signals, a motion parameter of the motion of the object, the motion parameter being included in the motion-related information, and
generating, based on the plurality of navigator signals, a data-consistency weighting matrix, the data-consistency weighting matrix comprising a plurality of weighting elements, each weighting element corresponding to a k-space point and representing a certainty level of the corresponding k-space point being corrupted by the motion of the object.

3. The method of claim 2, wherein the step of generating the data-consistency weighting matrix further comprises:
deriving, based on the received plurality of navigator signals, a reference navigator signal;
calculating a corresponding correlation between each navigator signal of the plurality of navigator signals and the reference navigator signal;
assigning, based on a comparison of the correlation calculated for each navigator signal, of the plurality of navigator signals, with an empirical correlation threshold, a particular value to a number of weighting elements of the weighting matrix, the number of weighting elements corresponding to a number of k-space points acquired by one of the plurality of shots that corresponds to the navigator signal.

4. The method of claim 3, wherein the assigned particular value is a value within a predefined range, and the assigning step further comprises:
assigning, in response to the comparison indicating a stronger correlation, the particular value, which approaches a first end of the predefined range to represent a higher certainty level of the number of k-space points not being corrupted by the motion, and
assigning, in response to the comparison indicating a weaker correlation, the particular value, which approaches a second end of the predefined range to represent a higher certainty level of the number of k-space points being corrupted by the motion.

5. The method of claim 3, wherein the assigned particular value is either a first predefined value or a second predefined value, and the assigning step further comprises:
assigning, in response to the comparison indicating the correlation beyond the empirical correlation threshold, the first predefined value to represent a high certainty level of the number of k-space points not being corrupted by the motion, and
assigning, in response to the comparison indicating the correlation short of the empirical correlation threshold, the second predefined value to represent a high certainty level of the number of k-space points being corrupted by the motion.

6. The method of claim 5, wherein the second predefined value is set at 0 to reject the number of k-space points because of the motion, such that the number of k-space points are not to be used in reconstruction of the image data, and the estimating step is omitted.

7. The method of claim 2, wherein the step of generating the data consistency weighting matrix further comprises:
inputting the plurality of navigator signals to a neural network; and
obtaining, as the data consistency weighting matrix, an output of the neural network.

8. The method of claim 7, further comprising:
obtaining motion-free navigator data;
determining different motions to be simulated;
generating motion-affected navigator data by simulating a corresponding influence of each motion on the motion-free navigator data;
using the motion-free navigator data and the motion-affected navigator data to train the neural network, so as to learn a mapping from the motion-affected navigator data to a corresponding data consistency weighting matrix.

9. The method of claim 2, wherein the step of generating the data consistency weighting matrix further comprises:
determining, based on the plurality of navigator signals, a reference navigator signal;
calculating a corresponding correlation between each navigator signal of the plurality of navigator signals and the reference navigator signal;
inputting the calculated correlations to a neural network; and
obtaining, as the data consistency weighting matrix, an output of the neural network.

10. The method of claim 2, wherein the step of generating the motion-corrected image data further comprising:
applying the received data or the reconstructed image data, the weighting matrix, and the motion parameter to a neural network; and
obtaining, as the motion-corrected image data, an output of the neural network.

11. The method of claim 10, wherein the applying step further comprises applying the obtained data or the reconstructed image data, the generated weighting matrix, and the estimated motion parameter to a model-driven deep learning framework having a pre-determined number of iterations, where each iteration comprises a regularization unit and a data consistency unit.

12. The method of claim 11, wherein the regularization unit is a U-net, a residual U-net, a residual network, an inception-residual network, or a linear convolutional network.

13. The method of claim 12, wherein the regularization unit is a complex U-net, and a plurality of parameters of the complex U-net are shared across the pre-determined number of iterations.

14. The method of claim 11, wherein the data consistency unit uses a conjugate gradient iteration algorithm, a proximal gradient algorithm, an orthogonal matching pursuit algorithm, an iterative hard thresholding algorithm, a split Bregman-based algorithm, or a gradient descent algorithm.

15. The method of claim 10, further comprising:
obtaining fully-sampled motion-free k-space data acquired by a plurality of shots;
generating motion-corrupted k-space data by simulating corresponding influences caused by motions having different motion parameters on different shots;
generating navigator data corresponding to the motions having different motion parameters;
generating data-consistency weighting matrixes based on the navigator data;
using the fully-sampled motion-free k-space data, the motion-corrupted k-space data, the data-consistency weighting matrixes, and the motion parameters to train the deep learning framework, so as to learn a mapping from the motion-corrupted k-space data to the fully-sampled motion-free image data.

16. The method of claim 2, wherein the step of receiving the plurality of navigator signals further comprises acquiring the plurality of navigator signals from a non-imaging k-space echo inserted into a pulse sequence of the magnetic resonance imaging system, a respiratory bellow, an electrocardiogram signal, a camera with an external marker, a camera without an external marker, or a pilot-tone-based motion detection signal.

17. The method of claim 2, wherein the step of receiving the plurality of navigator signals further comprises acquiring the plurality of navigator signals in a form of a 3D volume, a 2D image, or a 1D signal.

18. The method of claim 2, wherein the estimating step further comprises estimating, as the motion parameter, a distance of a translation and/or an angle degree of a rotation.

19. A method for motion correction in a magnetic resonance imaging system, comprising:
acquiring k-space data from imaging an object by the magnetic resonance imaging system;
determining, based on a plurality of navigator signals acquired while the k-space data is being acquired, a certainty level of each k-space point of the acquired k-space data being corrupted by a motion of the object;
identifying, based on the determined certainty levels, a number of k-space points corrupted by the motion of the imaging object;
re-acquiring, with respect to the identified motion-corrupted k-space points, a number of k-space points;
determining, based on a plurality of navigator signals acquired while the re-acquired k-space points are being re-acquired, a certainty level of each k-space point of the re-acquired k-space data being corrupted by a motion of the object; and
using the acquired k-space data, the re-acquired k-space points, and corresponding certainty levels to reconstruct a magnetic resonance image.

20. A apparatus for motion correction in a magnetic resonance imaging system, comprising
processing circuitry configured to:
receive data collected from imaging an object by the magnetic resonance imaging system, or image data reconstructed from the collected data;
generate motion-related information with respect to a motion of the object while the collected data is being collected, the motion-related information including a certainty level of the collected data being corrupted by the motion of the object; and
generate, based on the obtained motion-related information and the obtained data or reconstructed image data, motion-corrected image data.
